(19) United States
(12) Patent Application Publication
(10) Pub. No.: US 2008/0063017 A1
(43) Pub. Date: Mar. 13, 2008

(54) Laser Diode Array Mounting

(75) Inventors: Claus Schnitzler, Kreuzau (DE); Holger Schlueter, Princeton, NJ (US)

Correspondence Address: FISH & RICHARDSON PC, P.O. BOX 1022, MINNEAPOLIS, MN, 55440-1022, US

(73) Assignee: TRUMPF PHOTONICS INC., Cranbury, NJ (US)

(21) Appl. No.: 11/569,832

(22) PCT Filed: Oct. 8, 2004
(86) PCT No.: PCT/US04/33331

§ 371 Date: Mar. 29, 2007

Related U.S. Application Data
(60) Provisional application No. 60/575,390, filed on Jun. 1, 2004.

(51) Int. Cl. H01S 5/42; H01S 5/024

(52) U.S. Cl. 372/35; 372/50.124

(57) ABSTRACT

An optically stacked, laser diode array module (10) includes a mounting block (100) having a series of stepped, parallel diode mounting surfaces (101) on one face of the block, each diode mounting surface cooperating with a respective pair of reference surfaces (102, 103) of the block to form a respective outside block corner, a series of laser diodes (300) affixed to the block, with facets of the diode aligned with the reference surfaces forming the outside block corner with the mounting surface on which the diode is disposed, such that a corner of each diode is aligned with a respective corner of the block, and a beam reflector (200) secured to the block and having a series of stepped, parallel surfaces, each positioned to intercept and reflect a respective one of the beams (500) from the laser diodes, such that the reflected beams are parallel and stacked. The beams (500) emitted from the laser diodes (300) can be collimated by microlenses (400).

### TECHNICAL FIELD

This disclosure relates to diode lasers, and more particularly to a module for mounting a plurality of laser diodes in an array.

### BACKGROUND

High-power diode lasers are used in many different applications. The usefulness of a laser for a specific application can be characterized by the laser's output power, the spectral line width of the output light, and the spatial beam quality of the output light.

The spatial beam quality can be characterized in several ways. For example, a wavelength independent characterization of the spatial beam quality is provided by the beam parameter product (“BPP”), which is defined as the product of the beam waist (i.e., the half diameter of the beam at the so-called “waist” position), wₒ, and the far-field, half-angle divergence of the beam, Θ_{O}:

BPP=ω₀Θ₀ (1)

As another example, a nondimensional characterization of the spatial beam quality is provided by the beam quality factor, M² or Q, where the beam quality factor is given by

M²=1/Q=πωₒθₒ/λ (2)

with λ being the wavelength of the output laser light.

A laser operating in the TEM₀₀ mode and emitting a Gaussian beam has the lowest possible BPP (M²=1). Ridge waveguide and gain-guided laser diodes operating in this mode are called single mode emitters and typically consist of a 3 μm wide stripe (along the lateral axis of the laser). The output power of these emitters is limited to about 1 W due to catastrophic optical damage (“COD”) of the laser facet. To increase the facet area, so called tapered emitters can be used.

To achieve higher power output from a semiconductor laser diode, a relatively wide effective lateral width of the active material in the laser can be used. Such devices are known as “wide stripe emitters,” broad stripe emitters,” or “multimode devices.” However, when the effective lateral width of the active material is greater than several times the laser output wavelength, gain can occur in higher order spatial modes of the resonant cavity, which can reduce the spatial beam quality of the output laser light.

Multiple wide stripe emitters and/or single mode emitters can be fabricated side-by-side on a single chip to make an array of single emitters. The output light of multiple individual laser diode emitters in an array can be combined incoherently to increase the overall output power from the chip. However, the beam quality of the combined output beam generally decreases with the number of individual emitters in an array.

The total output beam of these laser diode arrays is generally strongly asymmetric. For example, a typical beam product parameter (“BPP”) of a 10 mm wide array along the slow axis (i.e., the lateral axis of the laser diode) can be BPP_{slow}=500 mm*mrad, while a typical BPP of an array along the fast axis (i.e., the vertical axis of the laser diode), where the device is typically operating in the TEM₀₀ mode, can be BPP_{Fast}=0.3 mm*mrad.

Many laser applications require a symmetric beam. However, it is difficult to symmetrize the strongly asymmetric beam of the array. The output beam of an array can be cut into parts and rearranged (e.g., by step mirrors, tilted plates, or tilted prisms), so that the BPP of the rearranged beam is equal in both axes, but complicated optical systems are necessary to achieve a symmetric beam in such a manner. All these systems have less then 100% transmission efficiency. Therefore, it is desirable to have a light source that produces a symmetric high power output beam without utilizing optical systems that cut the output beam from one or a plurality of arrays into parts. Moreover, it is desirable to have a way of mounting a plurality of laser diode arrays for creating such a high power beam.

### SUMMARY OF THE INVENTION

Several aspects of the invention feature an optically stacked, laser diode array module with a common mounting block to which a multiplicity of individual laser diodes are separately secured and positioned in such a way that their individual beams intercept a beam reflector and become optically stacked.

According to one aspect of the invention, an optically stacked laser diode array module includes a mounting block, a series of laser diodes affixed to the block, and a beam reflector secured to the block. The mounting block has a series of stepped, parallel diode mounting surfaces on one face of the block, each diode mounting surface cooperating with a respective pair of reference surfaces of the block to form a respective outside block corner. Each laser diode is disposed on a respective one of the diode mounting surfaces, with facets of the diode aligned with the reference surfaces forming the outside block corner with the mounting surface on which the diode is disposed, such that a corner of each diode is aligned with a respective corner of the block, one of the aligned facets of each diode defining an output facet from which a beam is emitted, perpendicular to the output facet, when the diode is activated. The beam reflector has a series of stepped, parallel surfaces, each positioned to intercept and reflect a respective one of the beams from the diodes, such that the reflected beams are parallel and stacked.

In, some cases, the beam reflector is secured to two orthogonal surfaces of the block that together locate the reflector with respect to the laser diodes. For greater positioning accuracy, one of the two orthogonal surfaces to which the beam reflector is secured may be parallel to the diode mounting surfaces of the mounting block.

In some embodiments the reflector is secured to the mounting block through an insulating layer. In some other cases, the reflector is secured directly to the mounting block, in direct contact with a surface of the mounting block.

Some embodiments also include a series of lenses, each lens disposed between a respective one of the diodes and the beam reflector. Each lens may be affixed to a corresponding one of the reference surfaces of the mounting block, such as with adhesive. In some configurations the lenses each define a cylindrical axis parallel to the output facet of its respective diode. The lenses are preferably adjustable during mounting, to align the output beam of its respective diode.

In some embodiments an electrically conductive voltage plate is secured to the mounting block and arranged to conduct electrical energy into an n-surface of each laser diode. In some cases the voltage plate is directly connected to each laser diode, such as by wire bonds, to provide power to the diodes in parallel. In some other cases, the voltage plate is directly connected to one of the laser diodes, others of the laser diodes arranged to receive electrical power in series from the diode to which the voltage plate is directly connected.

The mounting block preferably defines a cooling passage within the block, for circulation of cooling fluid to remove heat generated by operation of the laser diodes. In some configurations, the mounting block includes an upper section and a lower section permanently joined along planar surfaces of the upper and lower sections to define the cooling passage. The upper section may define the diode mounting surfaces and the outer corners to which the diodes are aligned, for example. Preferably, the cooling passage passes directly under at least one of the mounted diodes.

In some embodiments the laser diodes are secured directly to the diode mounting surfaces of the mounting block, such as by being soldered directly to the diode mounting surfaces. In some other embodiments, the laser diodes are affixed to the mounting block through submounts of a material selected to have a thermal expansion characteristic similar to that of the diodes. The submounts may electrically insulate the diodes from the mounting block, for example.

Preferably, the diode mounting surfaces of the mounting block have a surface roughness of less than about 0.02 microns. More preferably, the reference surfaces of the mounting block also have a surface roughness of less than about 0.02 microns.

In a presently preferred construction, each diode mounting surface and its respective pair of reference surfaces are all perpendicular to one another at their mutual corner, such that the corner is square.

Another aspect of the invention features a solid state laser comprising multiple laser diode modules each constructed as described above, along with optics arranged to combine the beams from the multiple laser diode assemblies into a single beam.

In some arrangements the multiple laser diode modules are each mounted against a first common mounting surface and arranged such that their output beams are parallel. For example, in one illustrated configuration the laser diode modules are arranged in a series, with alternating ones of the series mounted against a second common mounting surface, such that the beam reflectors of all of the modules of the series are overlapped, alternating ones of the beam reflectors facing in opposite directions.

In some cases, the first and second common mounting surfaces are perpendicular.

Some examples also include a fiber coupler with an integrated focusing lens that focuses the single beam into a fiber.

Another aspect of the invention features a method of assembling an optically stacked laser diode module. The method includes affixing a series of laser diodes to a mounting block having a series of stepped, parallel, diode mounting surfaces on one face of the block, each diode mounting surface cooperating with a respective pair of reference surfaces of the block to form a respective outside block corner, each laser diode disposed on a respective one of the diode mounting surfaces, with facets of the diode aligned with the reference surfaces forming the outside block corner with the mounting surface on which the diode is disposed, such that a corner of each diode is aligned with a respective corner of the block, one of the aligned facets of each diode defining an output facet; securing a beam reflector to the block, the reflector having a series of stepped, parallel surfaces each positioned to intercept and reflect a beam generated by a respective one of the diodes; securing a series of lenses to the mounting block, each lens disposed between a respective one of the diodes and the beam reflector; activating each of the laser diodes to generate a beam emitted perpendicular to the output facet; and adjusting a position of at least one of the lenses to align the beam emitted from its associated diode.

Preferably, the lenses are each adjusted as they are secured to the mounting block, such as with adhesive.

Another aspect of the invention features a method of positioning and securing multiple laser diodes on a common mounting block. The method includes providing a mounting block having a series of stepped, parallel, diode mounting surfaces on one face of the block, each diode mounting surface cooperating with a respective pair of reference surfaces of the block to form a respective outside block corner at which the diode mounting surface and respective pair of reference surfaces defining the corner are all perpendicular to one another, such that the corner is square; placing the mounting block in a fixture with surfaces that locate the mounting block with respect to the fixture by contacting each of the reference surfaces of the block, pairs of perpendicular surfaces of the fixture coinciding with pairs of perpendicular surfaces of the block at each of the outside block corners, with the laser diode mounting surfaces exposed; placing a laser diode on each of the laser diode mounting surfaces, with two side surfaces of each laser diode abutting an associated pair of the perpendicular surfaces of the fixture to align the side surfaces of the laser diode with associated reference surfaces of the mounting block; and affixing the laser diodes to the mounting block in their aligned positions.

In various embodiments discussed in more detail below, the laser diodes are placed on steps with particularly accurate height displacement enabled, at least in part, by the configuration of the mounting block. Perpendicular to each of these steps two surfaces (perpendicular to each other) are provided. The first of the two surfaces serves as an end stop for the out coupling facet of the laser diode. This ensures that the emission of the laser diode is exactly perpendicular to that surface. The second of the two surfaces serves as an end stop for the side facet of the laser diode. This surface is also accurately displaced from all the other second surfaces that belong to the plurality of steps, that the laser diodes are accurately positioned with the desired lateral distance between them. Together with accurate height displacement, the configurations described herein can ensure that the plurality of laser beams emitted from the laser diodes are accurately spaced in three orthogonal directions and parallel to each other, enabling more ready optical stacking of the individual beams.

Several examples described below also feature a step mirror attached to an accurately machined surface with two additional end stops (again two surfaces perpendicular to the machined surface) so as to ensure proper alignment of each of the individual steps of the step mirror to each of the parallel beams from the diodes. The step mirror serves the purpose of accurately stacking the parallel laser beams on top of each other. The three surfaces that define the position of the step mirror are accurately machined with respect to the diode mounting and reference surfaces of the mounting block. This ensures that the beams will be very accurately placed on top of each other without major alignment expenditure.

One set of orthogonal reference surfaces also serves as the attachment base for cylindrical microlenses. Arranging the lenses with their cylindrical axes being substantially perpendicular to the reference surface to which they are secured can greatly facilitate alignment of the microlenses and ensures that the adhesive used to attach the microlens shrinks substantially in such a way that only a displacement of the microlens along the cylindrical axis occurs, so as to have minimal or no optical effect. Because the microlenses can be individually secured and adjusted after the step mirror is attached, adjustment of the lenses can be sufficient as the only alignment step required for the completely assembled module, even accommodating some positioning errors between the block and step mirror.

A plurality of such fully adjusted, multiple-diode modules or “M-blocks” can be combined in such a way as to multiply the number of laser beams stacked optically on top of each other. An example described below features a center mount with two surfaces that are perpendicular to each other. Each surface holds M-Blocks at different heights such that the step mirrors alternately stack beams from M-Blocks attached to the first and the second surface on the center mount. This ensures that the beams of an unlimited number of laser diodes can accurately be stacked on top of each other without great alignment expenditure, since the surfaces of the M-Blocks that attach to the accurately machined surfaces of the center mount are accurately machined with regards to the diode mounting and reference surfaces of the M-blocks.

The M-Blocks can be electrically insulated from each other by coating the center mount with an electrical insulator (such as Aluminum oxide).

The laser diodes on the M-Block can be driven electrically parallel by utilizing a proper n-contact voltage plate which also contains steps of accurate height displacement. Alternatively, the laser diodes on the M-Block can be driven electrically in series by utilizing a proper system of conductive and insulating shims for the n-contact The M-block can be actively water cooled utilizing any laser diode heat sink cooling method, such as simple drilled holes with plugs; milled cooling channels in a part containing a lid and a base, where the lid is hard soldered to the base; a substrate that is made from DCB (direct bonded copper); or a substrate made from micro channel coolers or finned coolers.

The center mount can be accurately placed on a base plate so that the plurality of stacked laser beams from the plurality of M-Blocks on the center mount can be accurately combined with the plurality of stacked laser beams from the plurality of M-Blocks on another center mount with opposite state of polarization.

Several center mounts can be accurately placed on a base plate so that the plurality of stacked laser beams having one specific wavelength from the plurality of M-Blocks on one center mount can be accurately combined with the plurality of stacked laser beams having another specific wavelength from the plurality of M-Blocks on another center mount.

Using the techniques stated above, the emission of the laser diodes on center mounts with any number of specific wavelengths and two states of polarizations can be combined.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a perspective view of a partially assembled module with multiple, optically-stacked laser diodes.

FIG. 2a is a front view of the module of FIG. 1, with step mirror removed and voltage plate attached.

FIG. 2b is an enlarged front view showing placement of the microlenses.

FIG. 3 is an exploded view of the module of FIG. 1, with voltage plate and insulators.

FIGS. 4a and 4b are top and side views of the module of FIG. 1, fully assembled.

FIG. 4c and 4d are enlarged views of areas 4c and 4d in FIGS. 4b and 4a, respectively.

FIG. 5 illustrates a microlens being secured and adjusted in the assembly of the module of FIG. 1.

FIGS. 6a, 6b and 6c are schematic views of the voltage plate of the module of FIG. 3.

FIG. 7a is a perspective view of a partially assembled module including a module block formed of two pieces.

FIG. 7b shows a schematic exploded view of the two block components joined to form the block of the assembly of FIG. 7a.

FIG. 8 is a bottom view of the upper component of the mounting block shown in FIG. 7a.

FIG. 9a is a top view of the lower component of the mounting block shown in FIG. 7a, while FIG. 9b is a cross-sectional view taken along line 9b-9b in FIG. 9a.

FIG. 10 is a top view of the partially assembled module of FIG. 7a, showing internal cooling passages.

FIGS. 11a and 11b show cross-sectional views of alternative mounting block constructions comprising laminates.

FIGS. 12a and 12b are cross-sectional views of alternative diode mounting arrangements, illustrating submounts.

FIGS. 13a and 13b show alternative methods of electrically connecting the laser diodes to a voltage plate.

FIG. 14a is a perspective view of a module with the diodes connected in series to the voltage plate, while FIG. 14b is an enlarged view showing current flow between diodes.

FIG. 15 is an exploded view of the module assembly shown in FIGS. 14a and 14b.

FIG. 16 is a perspective view of the module block of the assembly of FIG. 3 in an alignment fixture for positioning the laser diodes for mounting.

FIGS. 17a-17c are perspective, side and end views, respectively, of multiple laser diode modules mounted to a single mounting block to form a multi-module assembly.

FIGS. 18 and 19 are top and perspective views, respectively, of a fiber-coupled diode laser system including four multi-module assemblies of the type shown in FIG. 17a, combined with other optical components.

FIGS. 20 and 21 are perspective views of another module construction having a step mirror insulated from the mounting block.

Like reference symbols in the various drawings indicate like elements.

### DESCRIPTION

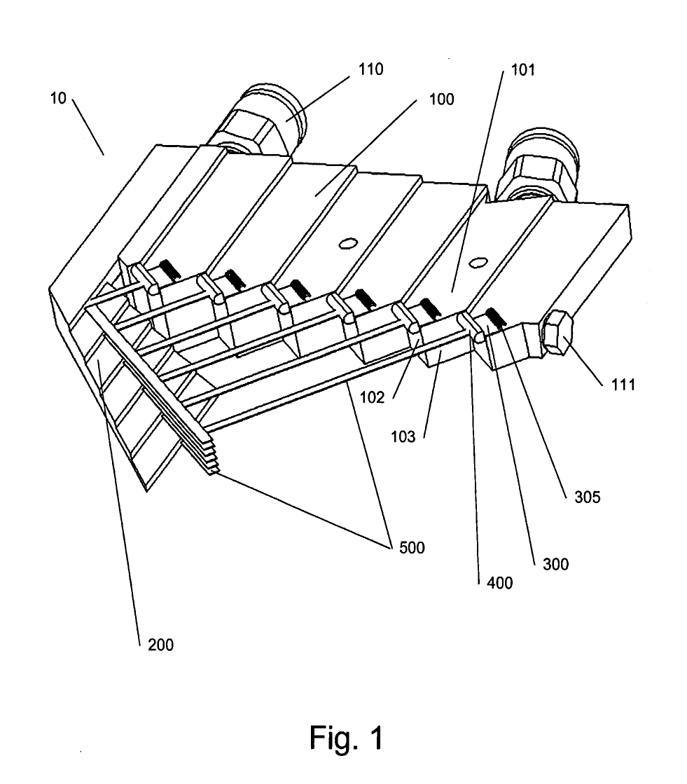

FIG. 1 shows an M-Block assembly 10 consisting of an M-Block 100 and a step mirror 200. The M-Block 100 has a plurality of steps (e.g., six steps) 101 that are parallel to each other with an accurately machined heights relative to each other.

Perpendicular to each of the steps 101 is a first surface 102 and a second surface 103. Surfaces 102 and 103 are also perpendicular to each other. The design of the plurality of surfaces 101, 102 and 103 is such that they can be machined by milling surfaces on the M-Block 100 using only three different orientations between the milling tool and the M-Block. Because each mounting surface 101 is parallel to the other mounting surfaces, each surface 101, as well as one of the locating surfaces for mounting of step mirror 200, may be diamond-milled with the M-block fixtured in a single position, minimizing tolerance errors and ensuring parallelism. Similarly, all parallel surfaces 102 may be milled with the M-block held in a single orientation, as can all parallel surfaces 103. All three sets of surfaces may be milled in orientations in which the M-block is held in locations determined by a common set of surfaces or features, including a surface that locates the M-block in use in a laser assembly. The step mirror 200 is secured to the M-Block after machining, such that the M-Block 100 is machined separately from the step mirror 200.

Each of the surfaces 102 provides an end stop against which the out coupling facet of a light emitting device (e.g., a semiconductor diode laser) 300 can be aligned so that the laser beam 500 emitted from any such laser diode 300 is perpendicular to all surfaces 102. The laser diode 300 can include one or more emitting regions, which can be part of a single chip light emitting device, and, when the chip includes more than one emitting region, the chip may be known as a light emitting array (e.g., a diode laser array). Because each laser diode 300 is aligned so that the laser beam 500 emitted from the laser diode 300 is perpendicular to all surfaces 102, all laser beams 500 are parallel to each other without any active alignment of the lasers 300 or their output beams 500.

Each of the surfaces 101 provides an end stop for a bottom facet of the laser diodes 300. Since the surfaces 101 are machined in the M-Block 100 at an precisely machined relative heights to each other the vertical displacement of all parallel laser beams 500 emitted from the lasers 300 are aligned with precise relative heights to each other.

Each of the surfaces 103 provides an end stop for one of the side facets of the laser diodes 300. Since the surfaces 103 are placed at an accurately machined distance from each other this ensures a precise horizontal distance between all parallel laser beams 500 when they are emitted from the lasers 300 and travel in the direction of the step mirror 200.

Surfaces 101, 102, and 103 therefore ensure that the beams of all laser diodes 300 are parallel to each other and precisely spaced horizontally and vertically from each other in all three Cartesian directions.

Step mirror 200 is accurately aligned to three surfaces on the M-Block not shown in FIG. 1, so that each mirror surface on the step mirror has a precisely defined orientation to the laser beam 500 it reflects and a precise distance to the laser diode 400 that emits the beam 500. The mirrors of the step mirror 200 deflect the laser beams 500 by 90 degrees and stack them on top of each other as shown in FIG. 1. After reflection from the step mirror 200, the optical path length of all laser beams 500 is identical. This is ensured by the proper placing of the step mirror surfaces and the surfaces 102.

Surfaces 103 also serve the purpose of allowing accurate placement of a plurality of microlenses 400 for focusing or collimating the beams 500 in the fast axis direction of the laser diodes 300. Surfaces 102 also serve the purpose of reference plane for the microlenses, ensuring the proper distance from the out coupling facets of the laser diode 300.

All laser diodes 300 can be electrically connected using wire bonds 305 or other appropriate means, such as, for example, n-contact shims. Also shown are water inlet and outlet fittings 110 and a plug 111, which can be used to achieve a specific active cooling of the M-Block 100 and the mounted laser diodes 300. Not shown in FIG. 1 are internal bores that transport the cooling fluid close to the laser diodes 300.

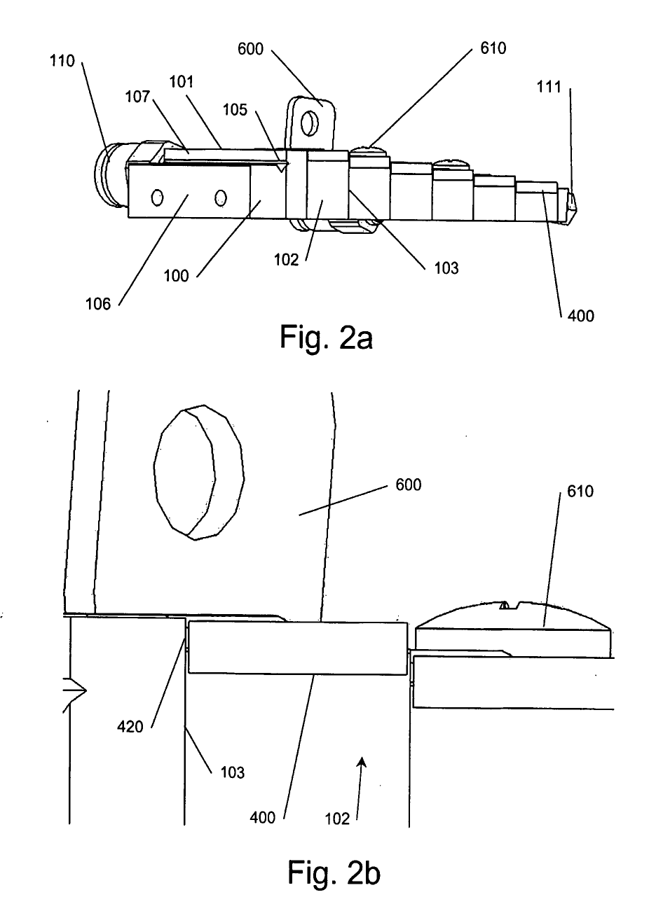

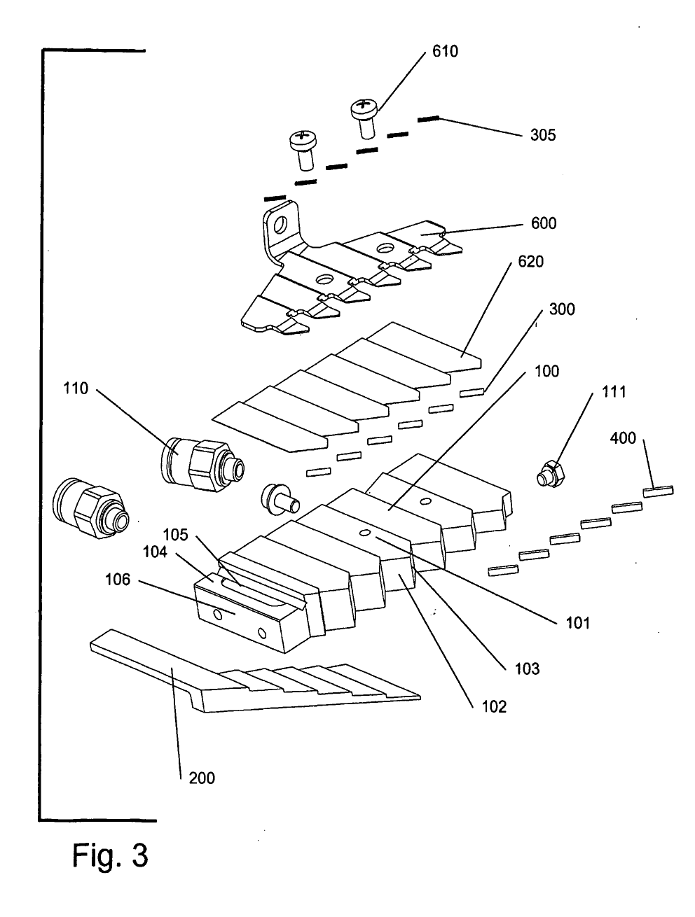

FIG. 2a shows the M-Block 100 in a plane parallel to surfaces 102. Clearly visible are the accurately placed microlenses 400, which have an accurate lateral and vertical distance from each other. Not visible is the accurate distance that microlenses 400 have in the direction perpendicular to surfaces 102. Visible is surface 106, which is manufactured accurately with respect to all surfaces 101, 102, and 103, such that it allows accurate attachment of the M-block to a center mount 20, as shown in FIG. 19a and described below. Surface 106 is perpendicular to surfaces 101 and is oriented at a 45 degree angle with respect to surfaces 102 and surfaces 103.

Visible is also the n-contact 600 that is attached to the M-Block using two non-conductive screws 610.

Microlenses 400 are placed at precise distances in lateral and vertical directions relative to each other to ensure optimum stacking of the beams 500 with maximum fill factor of the combined beam after reflection by the surfaces of the step mirror 200. Surfaces 104 and 107 ensure accurate placement of the step mirror 200, and surface 106 ensures accurate placement of a plurality of M-Blocks 100 on a center mount and therefore with respect to each other, as described in more detail below. Adhesive reservoir 105 is used to hold adhesive to glue the step mirror 200 to the M-Block 100. The surfaces 102 are parallel to each other at an precisely machined distances from each other in order to ensure an identical optical path length of the individual beams after reflection from the step mirror 200.

FIG. 2b shows the accurate placement of microlenses 400. The microlenses 400 are cylindrical lenses having an axis that is perpendicular to the surface 103. Between surface 103 and microlens 400 a gap 420 exists that holds adhesive for fixing the lens 400 in its proper location. During the curing process, the adhesive shrinks and results in movement of the microlens 400. The particular setup ensures that this shrinkage moves the microlens substantially along the cylindrical axis, which has no optical effect on the collimated beam 500.

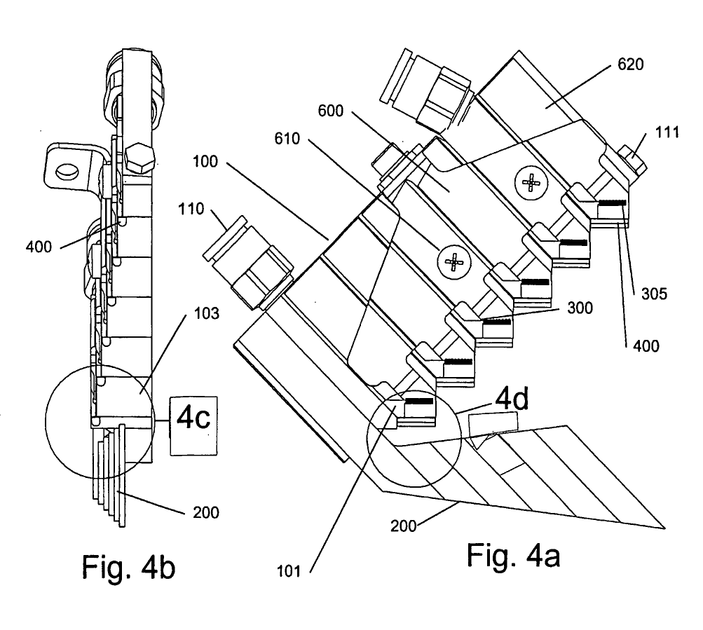

FIG. 3 is an exploded view of the entire M-Block assembly 100. Shown is the M-Block 100 with the plurality of surfaces 101, 102, and 103. The M-Block 100 contains perpendicular surfaces 104 and 107 (FIG. 2a) that allow accurate attachment of step mirror 200 and that ensures proper positioning of the step mirror 200 with respect to the laser beams 500. Surface 104 also contains a pocket 105 that serves as an adhesive reservoir in case the step mirror 200 is to be glued to the M-Block 100.

Fittings 110 and plug 111 are used to flow a cooling fluid through the M-Block 100 and route the fluid through simple bores to transport cooling fluid close to the plurality of laser diodes 300. Electrically insulating sheets 620 are placed on the surfaces 101 to insulate n-contact sheet 600 from the base of the M-Block 100 and two insulated screws 610 attach the n-contact sheet 600 to the M-Block 100. Electrical contact between the n-contact sheet and the diodes can be established by utilizing wirebonds 305 or other appropriate means.

To collimate the light emitted from the laser diodes 300 cylindrical microlenses 400 are used.

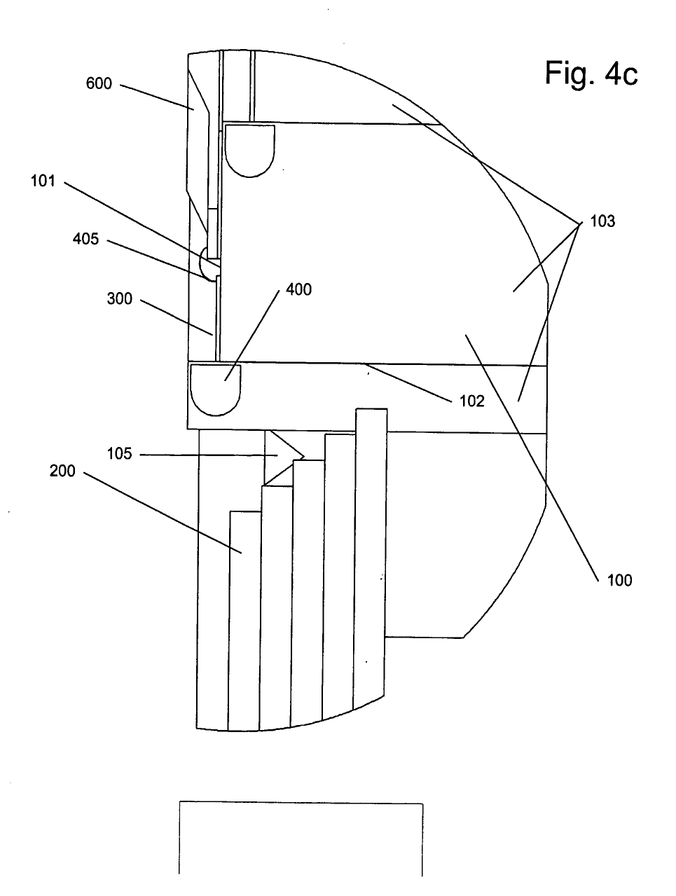

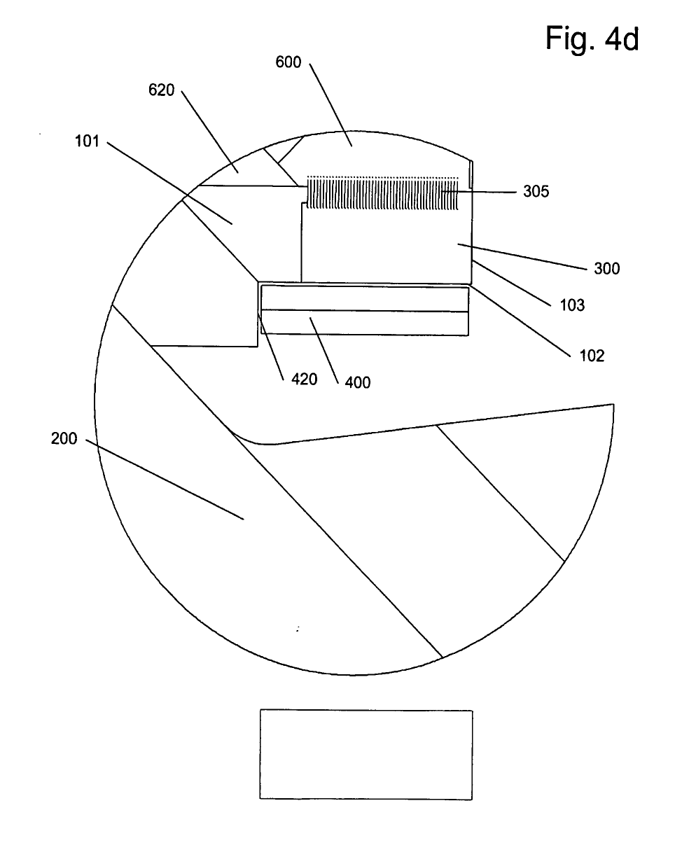

FIG. 4a shows a top view of a portion of the M-Block 100 that is parallel to surfaces 101. The n-contact sheet 600 and the screws 610 are visible as well as the insulating sheets 620. Wirebonds 305 connect the laser diodes 300 to the n-contact sheet 600. Microlenses 400 collimate the light emission of the laser diodes 300 in the fast axis direction. Facing each laser diode 300 is a mirror on the step mirror 200, which deflects the beam by 90 degrees and is located with respect to the laser diode 300 so as to ensure that the optical path length of all laser beams 500 is identical when the beams are combined.

Fittings 110 and Plug 111 allow a cooling fluid to flow through the M-Block 100 to cooling the block.

FIG. 4b shows a side view of a portion of the M-Block 100 that is parallel to surfaces 103. The mirrors of the step mirror 200 are oriented at an angle of 45 degrees to this plane. The cylindrical axis of the microlenses 400 is perpendicular to this plane. Surfaces 103 are parallel to each other and placed at precise distances relative to each other in order to ensure proper optical stacking of the beams.

FIG. 4c is a detailed view of a portion of FIG. 4b and shows a side view of M-Block 100 that is parallel to surfaces 103. The accurate placement of the cylindrical microlenses 400 with respect to the laser diodes 300 can be seen in FIG. 4d, which ensures proper collimation of the laser beams 500. The accurate positioning of the laser diodes 300 with respect to each other is also visible. In the case shown, the laser diodes 300 are electrically connected to the n-contact sheet 600 by wirebonds 305. The microlenses 400 and the laser diodes 300 are placed such that the radiation of the laser diodes 300 is reflected from the step mirror 200 with minimum loss. In case of a symmetrical intensity distribution in the fast axis of the collimated beam this means that the optical axis of each of the laser beams lies in the center of the corresponding step of the step mirror 200.

The groove 105 is part of the adhesive reservoir for attachment of the step mirror 200.

FIG. 4d is a detailed view of a portion of FIG. 4a and shows a top view of a portion of the M-Block 100, which is parallel to surfaces 101. From FIG. 4e it can be seen how the surfaces 103 and 102 serve as end stops for the accurate placement of the laser diodes 300. Also visible is the gap 420 that contains the adhesive for attachment of the microlens 400. The precise machining of surfaces 103 allows for extremely small gap width 420 (on the order of 10 μm or less) and therefore ensures a very controlled shrinking process during curing of the adhesive. In addition the specific choice of geometry will ensure that the shrinkage occurs substantially along the cylindrical axis of the microlens 400 and, therefore, that the shrinkage has no optical effect on the collimated beams 500. From FIG. 4e, it can be seen how the individual steps of the step mirror 200 are placed at an angle of 45 degrees with respect to surfaces 102 and 103 and therefore ensure accurate 90 degree deflection of the beams 500.

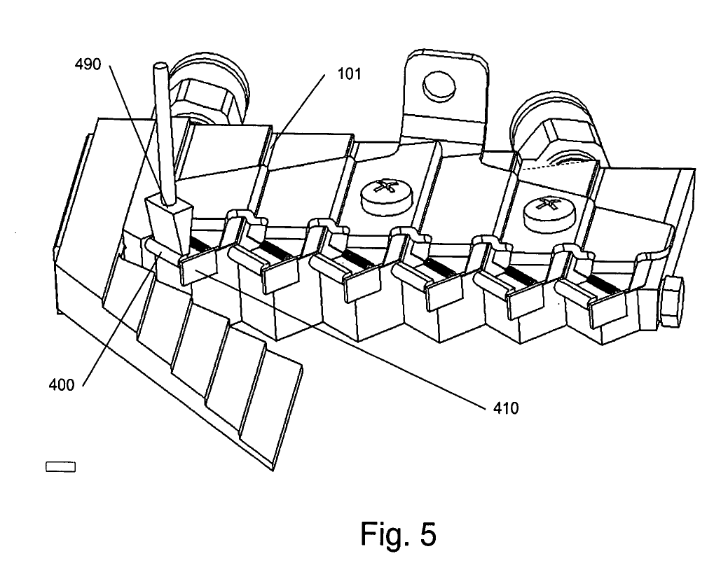

FIG. 5 shows how microlenses 400 can be aligned with respect to laser diodes 300 and with respect to each other and how the microlens alignment can occur after the attachment of the step mirror 200 to the M-Block 100. While the step mirror 200 can be very accurately placed with respect to surfaces 101, 102, and 103, a tolerance chain between the steps of the step mirror 200 and the out coupling facets of the laser diodes 300 exists that contains at least two interfaces. Therefore the active alignment of the microlenses 400 after attachment of the step mirror 200 can be utilized to compensate for any inaccuracy between the placement of the outcoupling facets of the laser diodes 300 and the steps of the step mirror 200. The microlenses 400 are placed in front of the laser diodes 300 using a vacuum collet 490 that is attached to a six axis alignment stage. During the active alignment, the position and the size of the deflected laser beam 500 at a large distance from step mirror 200 is adjusted until the beam 500 is perfectly collimated and is accurately placed in the proper vertical distance from the other laser beams (unless it is the first beam that is aligned) and in line with the other beams in horizontal direction. This approach advantageously allows the module to be completely assembled and adjusted as a replaceable unit.

If the laser beams 500 of multiple M-blocks 100 are to be aligned properly with respect to each other, an alignment fixture with a reference surface to which the M-Block surface 106 is accurately attached, and a template is placed at a large distance from the fixture the indicates the desired size and placement of the individual laser beams of each M-Block. That way the first of laser beams 500 of any M-Block is repeatably referenced to surface 106 and two perpendicular edges of surface 106 such that the laser beams 500 not only of one particular M-Block 100 are aligned accurately to each other, but that the laser beams 500 of multiple M-Blocks 100 are also aligned to each other, which can be useful if multiple M-Blocks 100 are placed on a center mount.

If the attachment of the microlens 400 to surface 103 of M-Block 100 at only one side of the microlens 400 is not reliable enough, a lens plate 410 can be attached to the other side of the microlens 400 and the neighboring surface 103 to hold the microlens 400 from both sides.

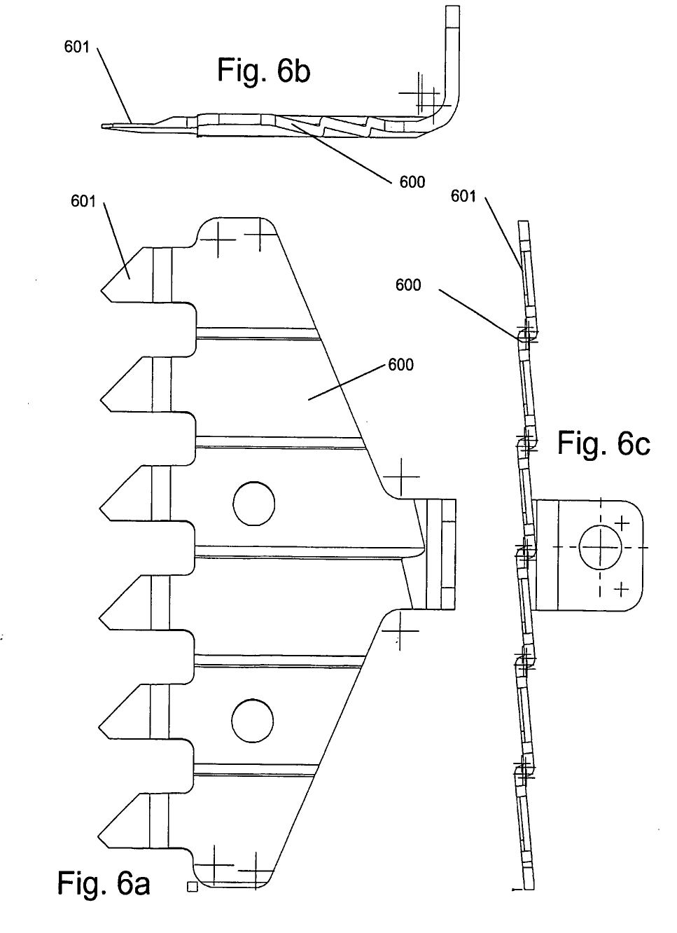

FIG. 6a shows a top view of the n-contact 600. A plurality of thinned regions 601 that allow attachment of wire bonds 305 are shown. The regions 601 are thinned, because the wire bond 305 typically does not allow for bridging a substantial height difference between the laser diode and the n-contact 600. On the other hand, the n-contact 600 should have a certain thickness to ensure stiffness and some heat removal capacity. Because of the limited ability to bridge height differences between surfaces 101 with a wire bond 305, the n-contact sheet 600 contains similarly spaced steps as the M-Block, parallel to surfaces 101. These steps in the n-contact sheet 600 can be very accurately and inexpensively fabricated using a coining operation.

FIG. 6b shows a side view of the n-contact 600, which shows the thinned regions 601 used for wire bonding.

FIG. 6c shows a side view of the n-contact 600, including the steps in the n-contact sheet 600.

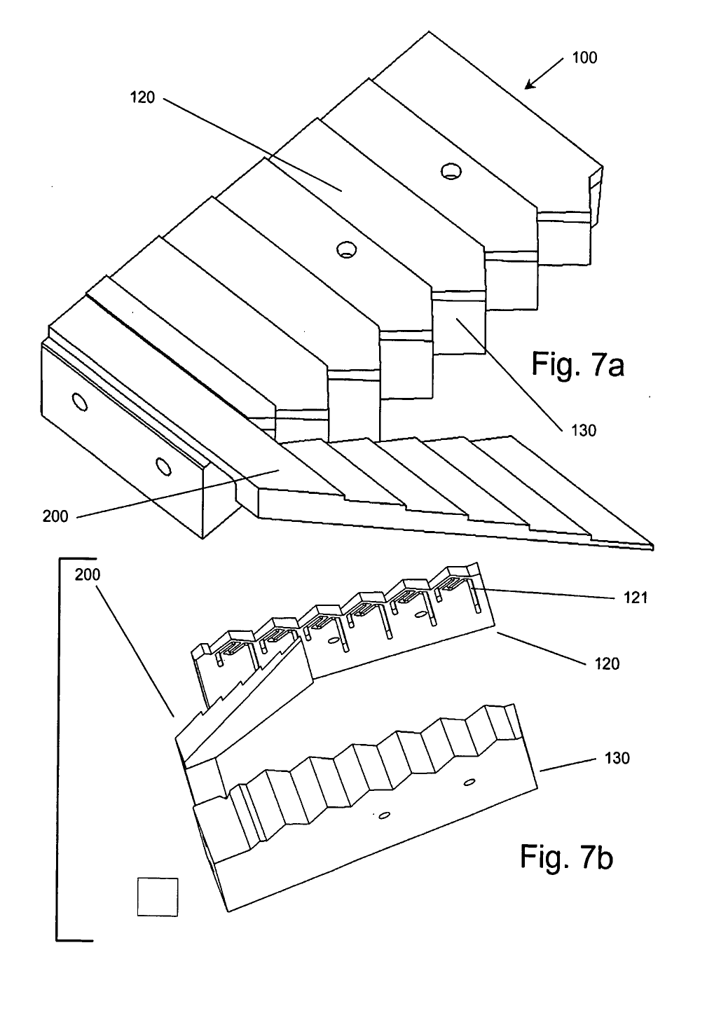

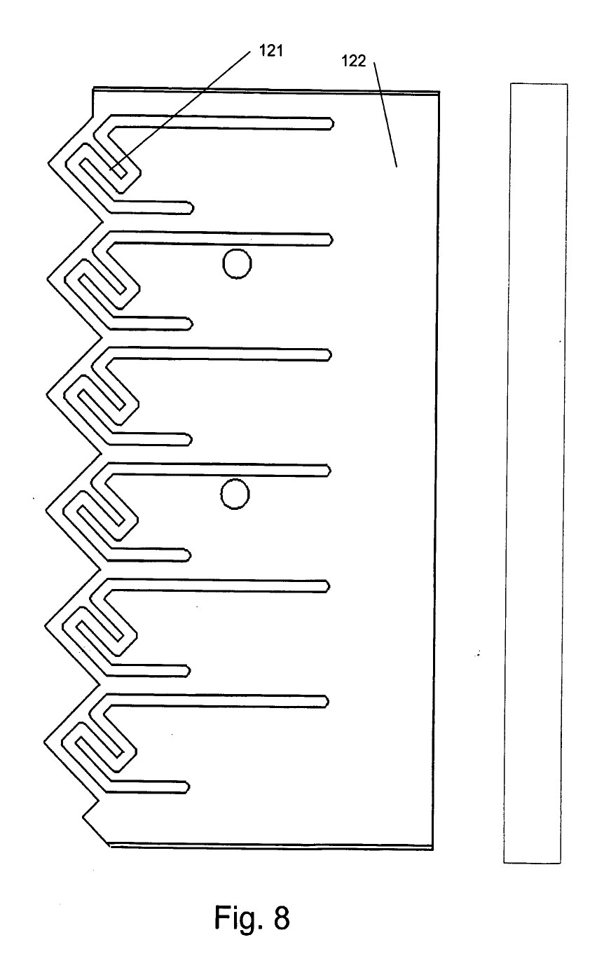

FIG. 7a shows an M-Block with a structure for an alternative cooling scheme. As shown, the M-block 100 includes a lid 120 and a base 130 that are brazed using hard solder. After brazing the surfaces 101, 102, 103, 114 and 106 are accurately machined. Step mirror 200 is attached to the finished M-Block 100, as describe above.

FIG. 7b shows an exploded view of this alternate cooling scheme. The lid 120 contains machined cooling channels 121 that ensure very homogenous cooling of the laser diodes 300. The cooling fluid is supplied to the cooling channels 121 in lid 120 through the base 130.

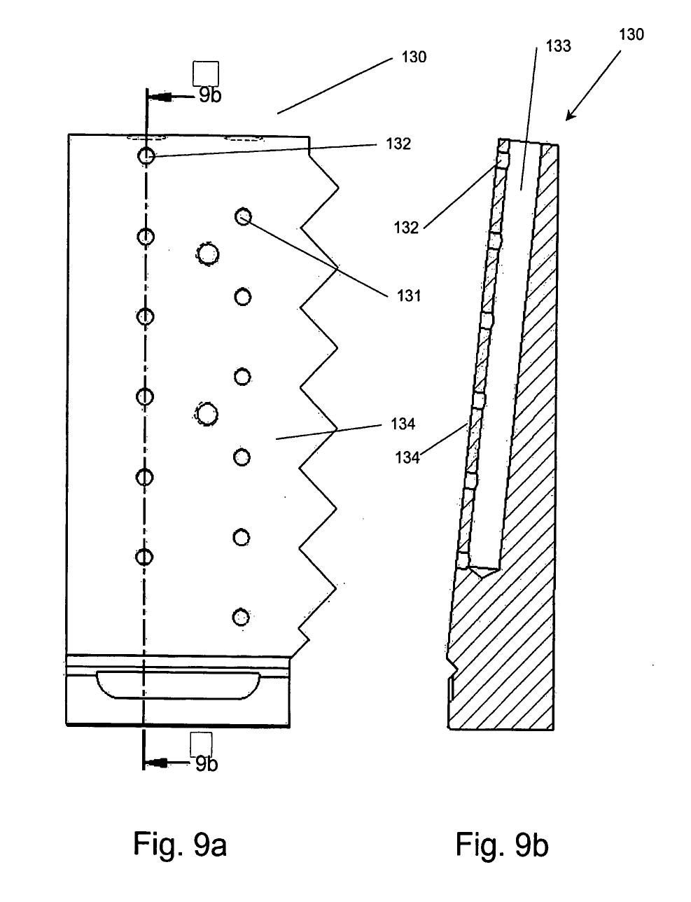

FIG. 8a shows a bottom view of the lid 120 in which the plurality of cooling channels 121 is clearly visible. The surface 122 is preferably flat to ensure very good hard soldering to the base 130.

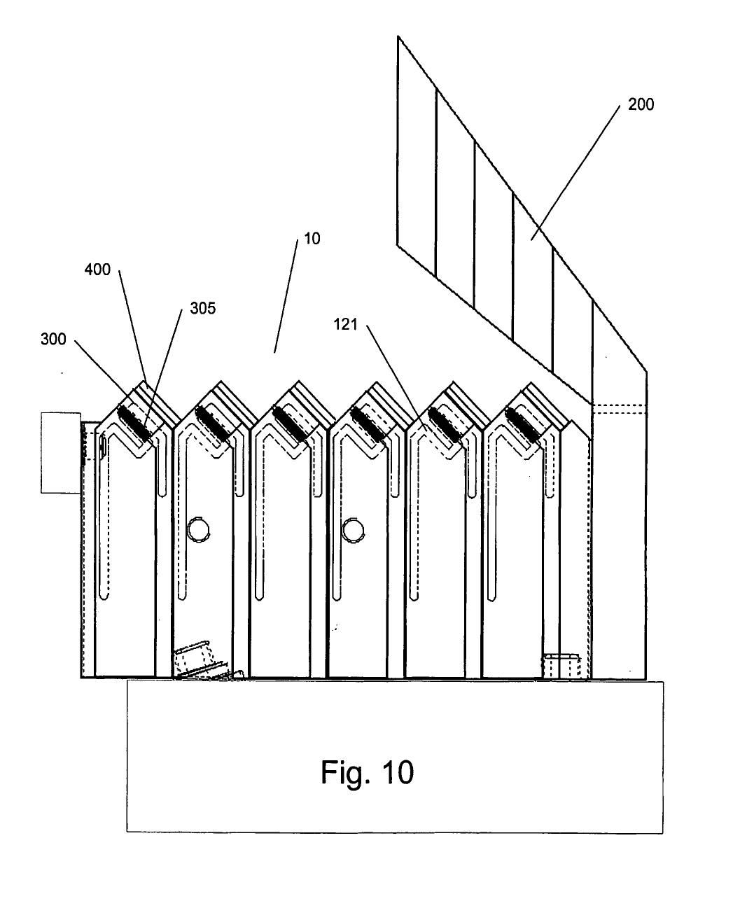

FIG. 9a shows a top view of the base 130, which contains a plurality of cooling fluid inlet bores 131 to feed the plurality of cooling channels 121 in the lid and a plurality of cooling fluid outlet bores 132 to remove the fluid from the cooling channels 121 in the lid. Surface 134 is the flat surface to which surface 122 of the lid can be soldered. A flat surface can be used to allow for very good solder joints.

FIG. 9b shows a side view of the base 130, which contains two cooling fluid manifold bores 133 (one of which is shown) to supply and remove the fluid from the plurality of fluid input bores 131 and water output bores 132.

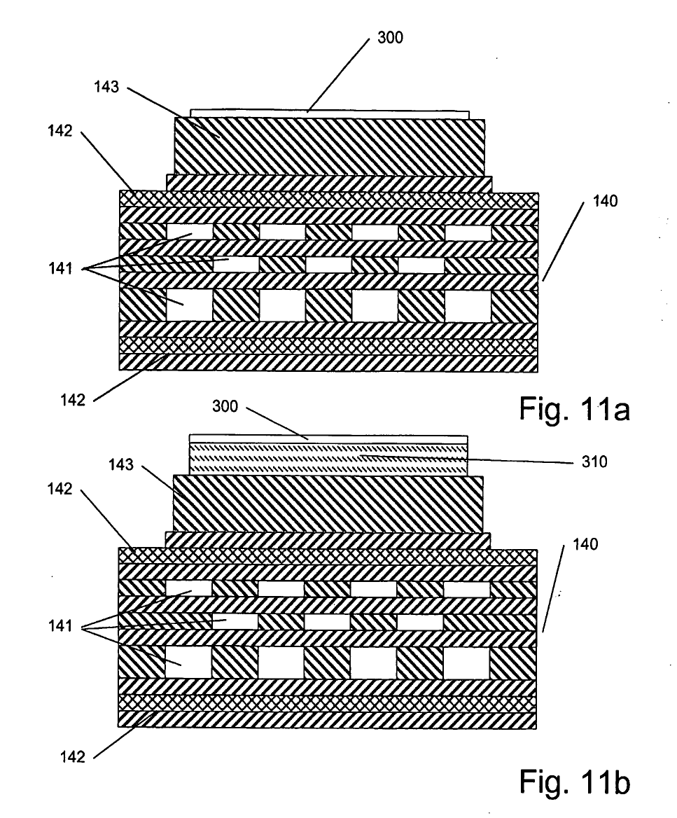

FIG. 10 shows a top view of ah entire M-Block assembly 10 that is built utilizing the alternative cooling scheme describe above. The plurality of cooling channels 121 beneath the plurality of laser diodes 300 is seen as a dashed line. Also visible are the step mirror 200, is the microlenses 400, and the wire bonds 305.

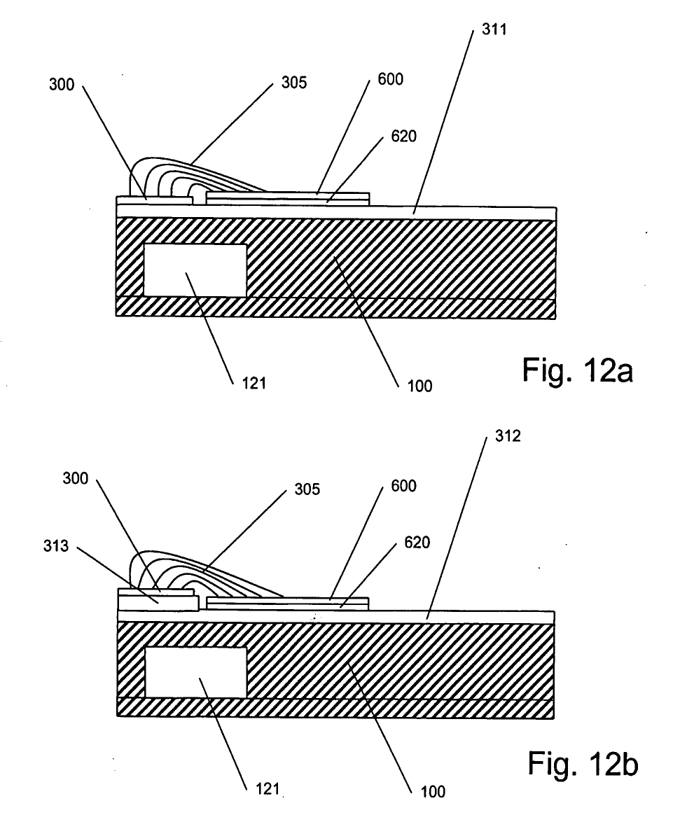

FIG. 11a shows another cooling alternative for the M-block 100 in which a direct copper bonded (DCB) substrate is used from which the M-Block 100 is machined. The direct copper bonded substrate includes two ceramic layers 142 and multiple cooling channels 141 that are formed by directly bonding sheets of metal. On top of the top most ceramic layer 142 a heat sink 143 is bonded, which is precisely machined as described above and on which the laser diodes 300 are directly placed.

FIG. 11b shows the same structure as FIG. 11a, except that a submount 310 is placed between the laser diode 300 and the heat sink 143. The submount 310 can be expansion matched to the crystalline material of the laser diode 300 to allow hard soldering of the laser diode 300. Such an expansion-matched submount 310 can be used with the other cooling schemes also.

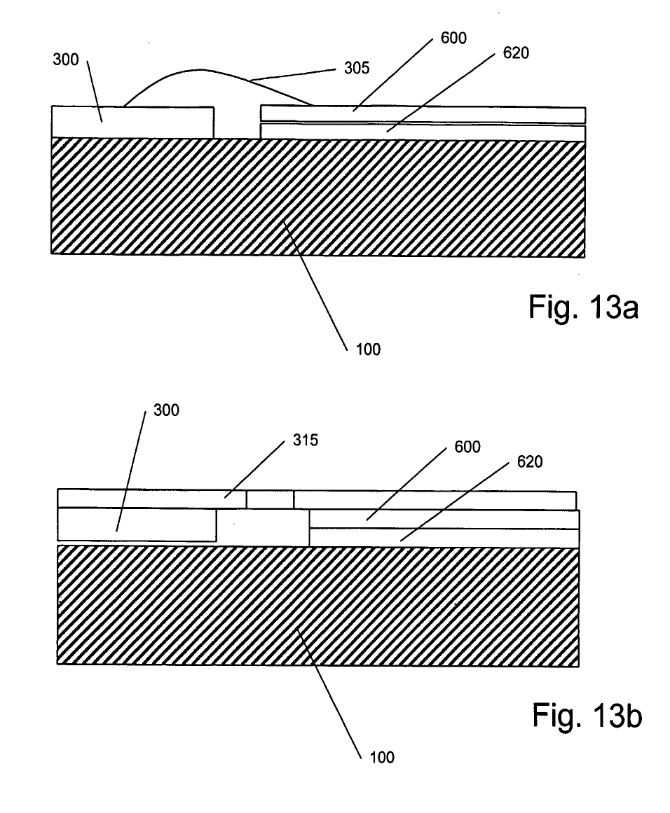

FIG. 12a shows one alternative mounting arrangement including an expansion matched submount 311 for hard soldering to the laser diode 300. The M-Block 100 contains cooling channels 121 formed by any of the mentioned cooling methods. The submount 311 is electrically insulating and the p-side of the laser diode 300 is hard soldered to the insulating submount 311. The n-side of the laser diode 300 is contacted to the n-contact sheet 600 by wire bonds 305 or any other appropriate method. The insulator 620 is optional.

FIG. 12b shows another mounting arrangement including an expansion-matched submount 313 for hard soldering to place the laser diode 300. The M-Block 100 contains cooling channels 121 formed by any of the mentioned cooling methods. The submount 313 is conductive, and the p-side of the laser diode 300 is hard soldered to a conductive submount 313. The n-side of the laser diode 300 is contacted to the n-contact sheet 600 by wire bonds 305 or any other appropriate method. The n-contact sheet 600 is isolated from the conductive submount 313 using an insulator 620, and the conductive submount 313 and the insulator 620 are placed on an insulator 312.

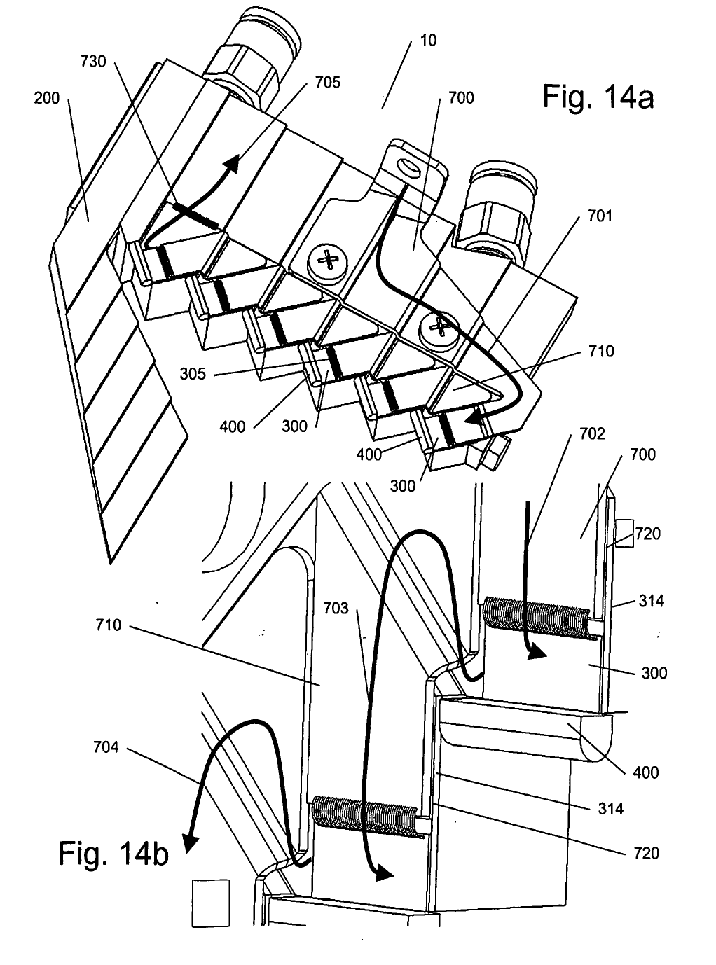

FIG. 13a shows generally how an electrical contact is made between the laser diodes 300 and the n-contact sheet 600 using wire bonds 305. The n-contact sheet 600 is insulated from the M-Block 100 using an insulator 620.

FIG. 13b shows, alternatively, how an electrical contact is made between laser diodes 300 and an n-contact sheet 600 using an n-contact shim 315. The n-contact sheet 600 is insulated from the M-Block using an insulator 620.

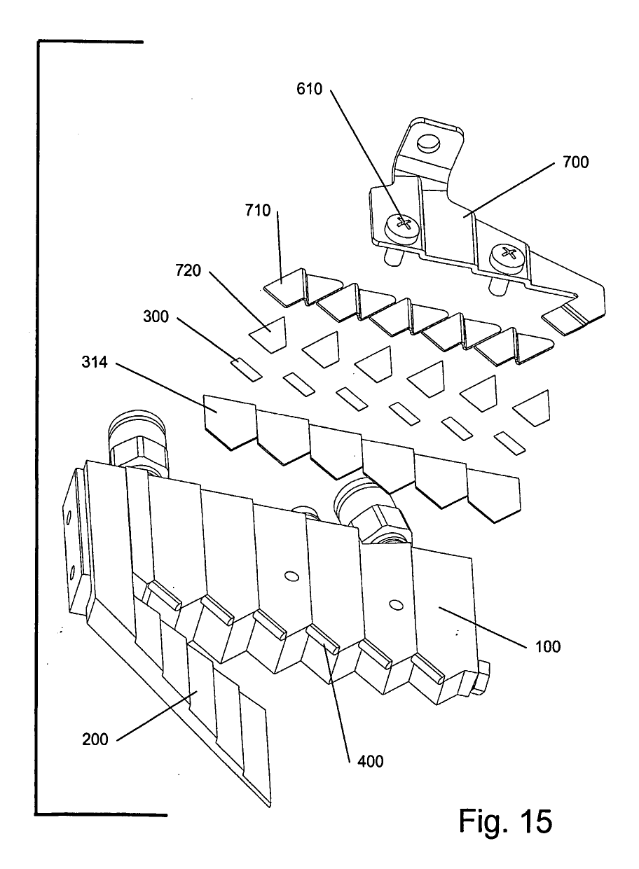

FIGS. 14a and 14b show how an M-Block 100 can be configured in order to drive all laser diodes 300 on the M-Block 100 in series. A series n-contact sheet 700 allows current flow 701 to the first laser diode 300. FIG. 14b shows a detail of FIG. 14a and shows how the current 702 flowing to the n-contact of the first laser diode 300, passes through the laser diode 300, and then the current 703 continues along a small n-contact shim 710 to the n-side of the second diode. It passes the second diode to its p-side, and form there the current 704 flows to the n-side of the next diode, and so on. FIG. 14 a shows how the current 705 flows from the p-side of the last diode through some end wire bonds to the M-block 100, which serves as the p-contact of the system of a plurality of laser diodes 300 in series with each other.

FIG. 14b also shows the conductive submount (or metal plated insulating submount) 314 and a small insulator 720 that insulates the small n-contact shims 710 from the submounts 314.

The insulator 720 between the small n-contact shims 710, the n-contact sheet 700 and the conductive or metal coated insulating submounts 314 are better visible. It is also clear how the current 702 flows into the n-side of a diode 300 and the current 703 flows out of the p-side to the next diode.

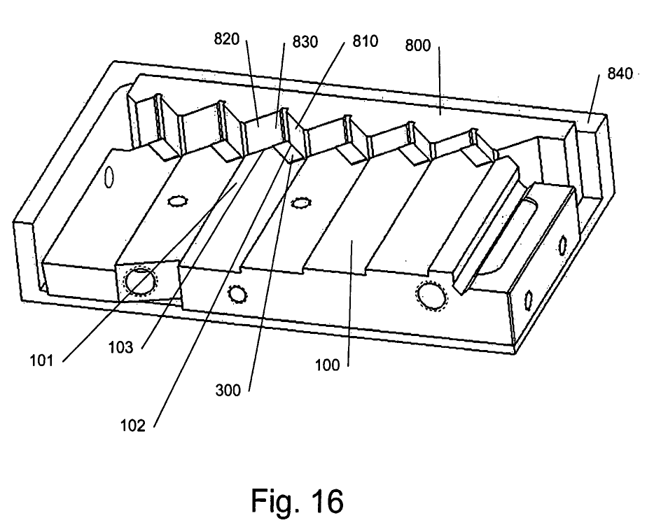

FIG. 15 shows an exploded view of an M-block 100 with all diodes in series. Visible are the step mirror 200, the microlenses 400, the M-Block 100, the conductive or metal-coated insulating submounts 314, the laser diodes 300, the insulators 720, the small n-contact shims 710, the n-contact sheet 700, and the insulating screws 610 that attach the n-contact sheet 700 to the M-block 100.

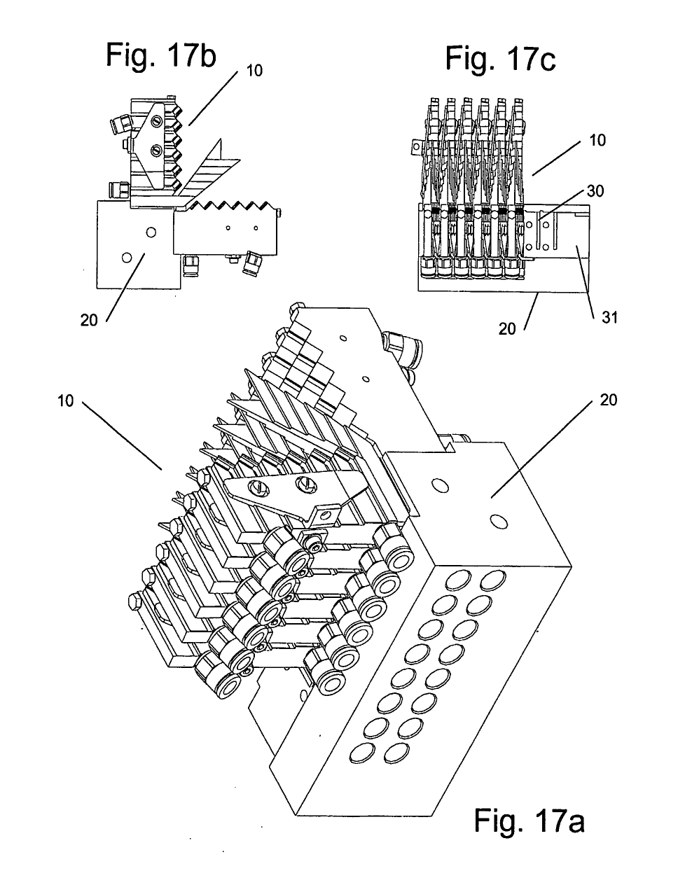

FIG. 16 shows how the laser diodes 300 can be aligned accurately to the surfaces 102 and 103 during the bonding processes. The M-block 100 is placed inside a holder 840. An accurately machined template 800 contains precisely machined surfaces 810 and 820. All surfaces 810 are parallel to each other, and all surfaces 820 are parallel to each other. Surfaces 810 are perpendicular to surfaces 820, and surfaces 810 are separated from surfaces 820 by an undercut 830. All surfaces 810 are brought into direct contact with all surfaces 102, and all surfaces 820 are brought into direct contact with surfaces 103. Such tolerances are possible because of the 1.0 μm accuracy of modern diamond machining tools.

The outcoupling facets of the laser diodes 300 are pushed against surfaces 810, with their side facets against surfaces 820 during the bonding process to ensure accurate placement of the laser diodes 300. The laser diodes then are bonded onto surfaces 101. In some cases, surfaces 810 of the alignment fixture are each slightly stepped, such that as aligned, the outcoupling facets of the laser diodes slightly overhang the diode mounting surfaces 101 of the mounting block, such as with an overhang of about 10 μm. This can help to ensure than no solder creeps up the output facet.

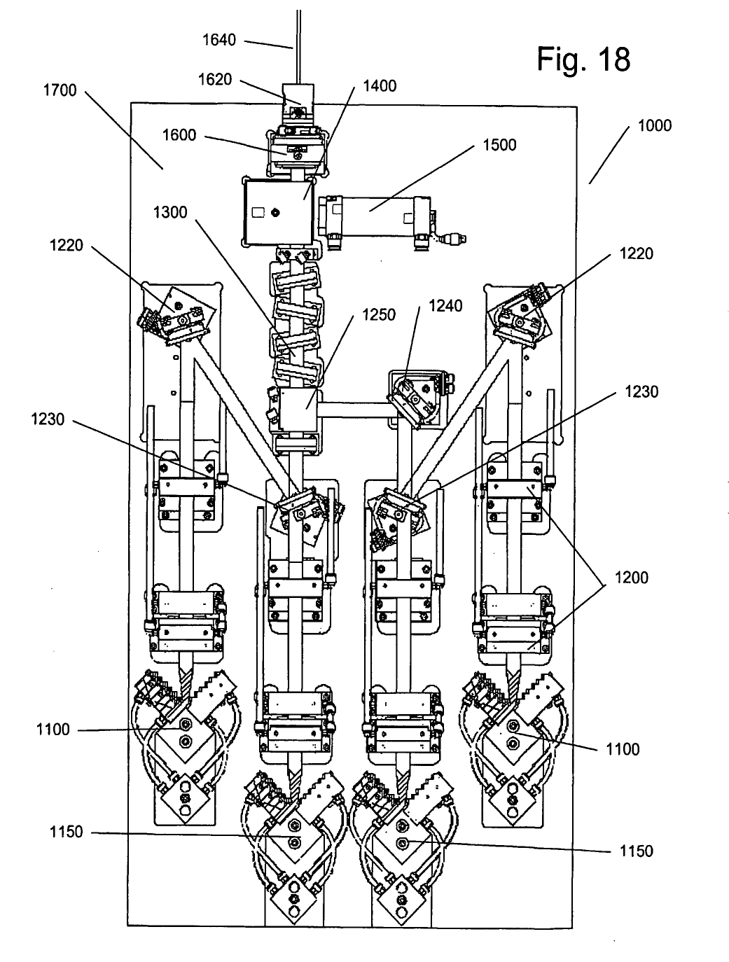

FIG. 17 shows a plurality of M-blocks 10 attached to a center mount 20. Because the center mount and the M-block surface 106 are accurately machined highly accurate placement of all laser diode beams on all M-blocks 10 can be achieved. The M-blocks 10 have a set distance from each other and are alternately placed on the two attachment surfaces of the center mount 20. On one of the attachment surfaces the M-blocks 10 are attached upside down to ensure a maximum number of total beams 500 in a minimum height, which corresponds to an optimum fill factor of the combined beam.

FIGS. 17b and 17c show end and side views of the center mount 20 including the M-block assemblies 10. Features 30 along common mounting surface 31 accurately position each M-block assembly on the center mount.

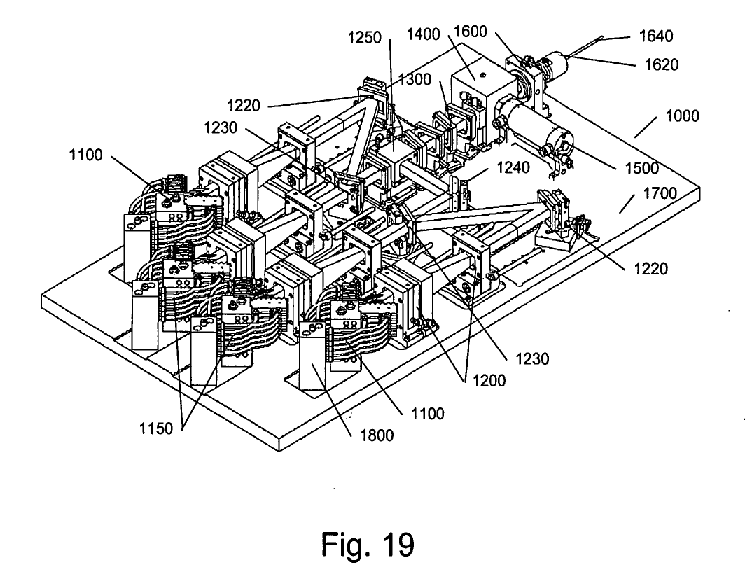

FIG. 18 shows a fiber coupled diode laser system based on two center mounted M-block stacks 1100 that emit light at a first wavelength and two center mounted M-block stacks 1150 that emit light at a second wavelength. All four center mounted M-block stacks 1100 and 1150 emit a stack of individual beams that are shaped using beam shaping optics 1200. After passing bending mirrors 1220, the radiation of the first wavelength is combined with the radiation of the second wavelength using dichroic mirrors 1230 that are transparent for the second wavelength and reflective for the first wavelength. This happens twice—once for the two stacks on the left side and once the two stacks on the right side.

One of the two remaining beams of the combined first and second wavelengths changes its state of polarization perpendicular to the other beams of the combined first and second wavelengths by passing a half-lambda plate 1240.

Then, the two remaining beams of the combined first and second wavelengths are polarization combined in a polarization combining prism 1250. The beam continues along a set of backscattering filters 1300 into a beam switch 1400. The beam can either leave the beam switch and propagate into a beam dump 1500 (laser on standby) or can propagate into a fiber coupler 1600 with an integrated focusing lens, which focuses the beam into a fiber 1640 that is fixed using a fiber plug 1620. The entire system is mounted on a base plate 1700.

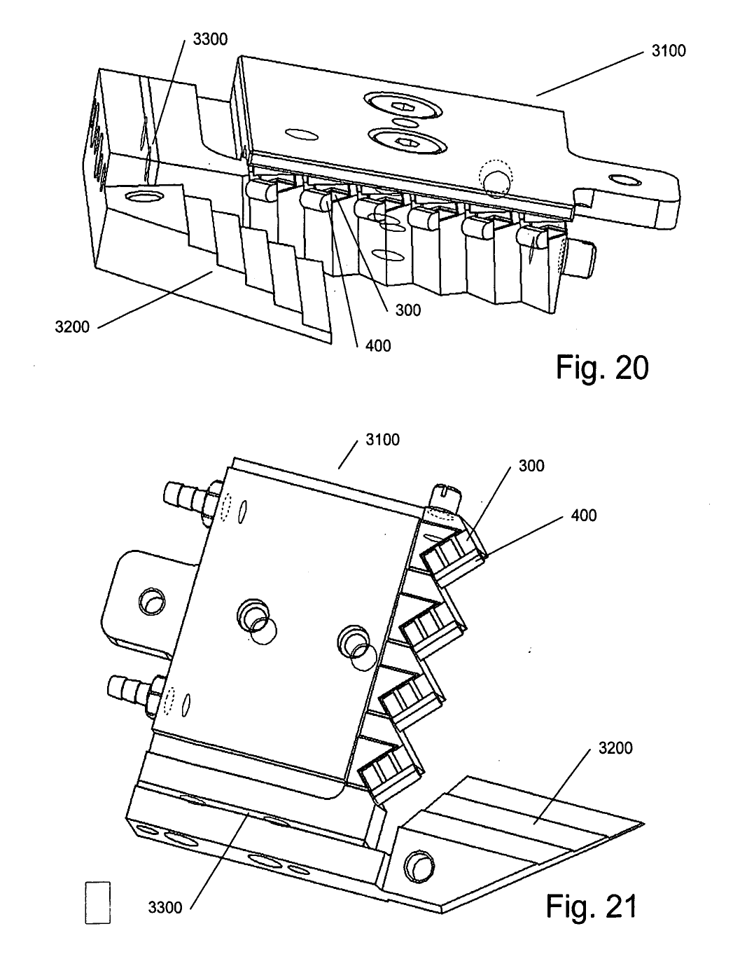

FIG. 19 shows a three dimensional view and details of the system described in FIG. 20.

FIG. 20 shows an alternative design of the M-block 3100. In this case, the alternative step mirror 3200 is isolated from the M-block utilizing an insulator 3300.

FIG. 21 shows another such alternative. In this case, each step surface 101 of the M-Block 100 includes a plurality of laser diodes 300, which can provide stress relief to the laser diodes 300 if they are hard soldered to a submount that is not perfectly expansion matched. Additionally, this configuration might also be beneficial for heat removal.

Other details regarding particular embodiments may be found in pending U.S. Provisional Patent Application Ser. No. 60/575,390, filed on Jun. 1, 2004, or in a U.S. Patent Application filed concurrently herewith by us and entitled DIODE LASER ARRAY STACK. The entire contents of both of these mentioned applications are hereby incorporated by reference.

A number of embodiments of the invention have been described. Nevertheless, it will be understood that various modifications may be made without departing from the spirit and scope of the invention. Accordingly, other embodiments are within the scope of the following claims.

1. An optically stacked, laser diode array module comprising:
a mounting block having a series of stepped, parallel diode mounting surfaces on one face of the block, each diode mounting surface cooperating with a respective pair of reference surfaces of the block to form a respective outside block corner;
a series of laser diodes affixed to the block, each laser diode disposed on a respective one of the diode mounting surfaces, with facets of the diode aligned with the reference surfaces forming the outside block corner with the mounting surface on which the diode is disposed, such that a corner of each diode is aligned with a respective corner of the block, one of the aligned facets of each diode defining an output facet from which a beam is emitted, perpendicular to the output facet, when the diode is activated; and
a beam reflector secured to the block, the reflector having a series of stepped, parallel surfaces, each positioned to intercept and reflect a respective one of the beams from the diodes, such that the reflected beams are parallel and stacked.

2. The module of claim 1 wherein the beam reflector is secured to two orthogonal surfaces of the mounting block that together locate the reflector with respect to the laser diodes.

3. The module of claim 2 wherein one of the two orthogonal surfaces to which the beam reflector is secured is parallel to the diode mounting surfaces of the mounting block.

4. The module of claim 1 wherein the beam reflector is secured to the mounting block tough an insulating layer.

5. The module of claim 1 wherein the beam reflector is secured directly to the mounting block, in direct contact with a surface of the mounting block.

6. The module of claim 1 further comprising a series of lenses, each lens disposed between a respective one of the laser diodes and the beam reflector.

7. The module of claim 6 wherein each lens is affixed to a corresponding one of the reference surfaces of the mounting block, such as by being adhered with adhesive.

8. The module of claim 6 wherein the lenses each define a cylindrical axis parallel to the output facet of its respective diode.

9. The module of claim 1 further comprising an electrically conductive voltage plate secured to the mounting block and arranged to supply conduct electrical energy into an n-surface of each laser diode.

10. The module of claim 9 wherein the voltage plate is directly connected to each laser diode to provide power to the diodes in parallel.

11. The module of claim wherein the voltage plate is directly connected to one of the laser diodes, others of the laser diodes arranged to receive electrical power in series from the diode to which the voltage plate is directly connected.

12. The module of claim 1 wherein the mounting block defines a cooling passage therein, for circulation of cooling fluid to remove heat generated by operation of the laser diodes.

13. The module of claim 12 wherein the mounting block comprises an upper section and a lower section permanently joined along planar surfaces of the upper and lower sections to define the cooling passage.

14. The module of claim 13 wherein the upper section defines the diode mounting surfaces and the outer corners to which the diodes are aligned.

15. The module of claim 1 wherein the laser diodes are secured directly to the diode mounting surfaces of the mounting block.

16. The module of claim 1 wherein the laser diodes are affixed to the mounting block through submounts of a material selected to have a thermal expansion characteristic similar to that of the diodes.

17. The module of claim 16 wherein the submounts electrically insulate the diodes from the mounting block.

18. The module of claim 1 wherein the diode mounting surfaces of the mounting block have a surface roughness of less than about 0.02 microns.

19. The module of claim 18 wherein the reference surfaces of the mounting block have a surface roughness of less than about 0.02 microns.

20. The module of claim 1 wherein each diode mounting surface and its respective pair of reference surfaces are all perpendicular to one another at their mutual corner, such that the corner is square.

21. A solid state laser comprising:
multiple laser diode modules each constructed according to claim 1; and
optics arranged to combine the beams from the multiple laser diode assemblies into a single beam.

22. The laser of claim 21 wherein the multiple laser diode modules are each mounted against a first common mounting surface and arranged such that their output beams are parallel.

23. The laser of claim 22 wherein the laser diode modules are arranged in a series, with alternating ones of the series mounted against a second common mounting surface, such that the beam reflectors of all of the modules of the series are overlapped, alternating ones of the beam reflectors facing in opposite directions.

24. The laser of claim 23 wherein the first and second common mounting surfaces are perpendicular.

25. The laser of claim 21 further comprising a fiber coupler with an integrated focusing lens that focuses the single beam into a fiber.

26. A method of assembling an optically stacked laser diode module, the method comprising:
affixing a series of laser diodes to a mounting block having a series of stepped, parallel, diode mounting surfaces on one face of the block, each diode mounting surface cooperating with a respective pair of reference surfaces of the block to form a respective outside block corner, each laser diode disposed on a respective one of the diode mounting surfaces, with facets of the diode aligned with the reference surfaces forming the outside block corner with the mounting surface on which the diode is disposed, such that a corner of each diode is aligned with a respective corner of the block, one of the aligned facets of each diode defining an output facet;
securing a beam reflector to the block, the beam reflector having a series of stepped, parallel surfaces each positioned to intercept and reflect a beam generated by a respective one of the diodes;
securing a series of lenses to the mounting block, each lens disposed between a respective one of the diodes and the beam reflector,
activating each of the laser diodes to generate a beam emitted perpendicular to the output facet; and
adjusting a position of at least one of the lenses to align the beam emitted from its associated diode.

27. The method of claim 26 Herein the lenses are each adjusted as they are secured to the mounting block.

28. A method of positioning and securing multiple laser diodes on a common mounting block, the method comprising
providing a mounting block having a series of stepped, parallel, diode mounting surfaces on one face of the block, each diode mounting surface cooperating with a respective pair of reference surfaces of the block to form a respective outside block corner at which the diode mounting surface and respective pair of reference surfaces defining the corner are all perpendicular to one another, such that the corner is square;
placing the mounting block in a fixture with surfaces that locate the mounting block with respect to the fixture by contacting each of the reference surfaces of the block, pairs of perpendicular surfaces of the fixture coinciding with pairs of perpendicular surfaces of the block at each of the outside block corners, with the laser diode mounting surfaces exposed;
placing a laser diode on each of the laser diode mounting surfaces, with two side surfaces of each laser diode abutting an associated pair of the perpendicular surfaces of the fixture to align the side surfaces of the laser diode with associated reference surfaces of the mounting block; and
affixing the laser diodes to the mounting block in their aligned positions.

29. The module of claim 6 wherein each of the lenses is adjustable during mounting to enable alignment of the output beam of the respective diode.

30. The module of claim 10 wherein the voltage plate is directly connected to each laser diode by wire bonds.

31. The module of claim 13 herein the cooling passage passes directly under at least one of the mounted diodes.

32. The module of claim 1 wherein the laser diodes are soldered directly to the diode mounting surfaces of the mounting block.
